(19) United States
(12) Patent Application Publication
(10) Pub. No.: US 2020/0326364 A1
(43) Pub. Date: Oct. 15, 2020

(54) Method of Diagnosing Oil-Immersed Electrical Apparatus

(71) Applicant: Mitsubishi Electric Corporation, Tokyo (JP)

(72) Inventors: Fukutaro OKAZAKI, Tokyo (JP); Satoru TOYAMA, Tokyo (JP)

(73) Assignee: Mitsubishi Electric Corporation, Tokyo (JP)

(21) Appl. No.: 16/707,189

(22) Filed: Dec. 9, 2019

(30) Foreign Application Priority Data
Apr. 9, 2019 (JP) 2019-074111

(51) Int. Cl. G01R 31/12

(52) U.S. Cl. CPC G01R 31/1263; H01F 27/321

(57) ABSTRACT

The present invention is related to a method of diagnosing an oil-immersed electrical apparatus by an assessment of a state of deterioration of the oil-immersed electrical apparatus, in which the oil-immersed electrical apparatus includes an insulating oil and an insulating paper and the insulating paper contains an amine compound. This method includes performing a quantitative analysis of a marker substance contained in the insulating oil and assessing a state of deterioration of the oil-immersed electrical apparatus based on a quantified value of the marker substance obtained by the quantitative analysis. The marker substance is a degradation product of cellulose, and this degradation product of cellulose does not chemically react with a deterioration product of the amine compound.

### BACKGROUND OF THE INVENTION

### Field of the Invention

The present invention relates to a method of diagnosing an oil-immersed electrical apparatus.

### Description of the Background Art

An oil-immersed electrical apparatus, such as an oil-immersed transformer, includes an insulating paper and a copper coil both disposed in insulating oil (namely, electrical insulating oil). The life of the oil-immersed electrical apparatus is greatly affected by the deterioration of the insulating paper, which is used for insulation of the winding. As the deterioration of the insulating paper proceeds, a marker substance for the deterioration (called herein a deterioration marker substance) is produced in the insulating oil. Analyzing the deterioration marker substance allows for diagnosis of the state of deterioration of the oil-immersed electrical apparatus, and there are techniques known for such diagnosis.

Conventionally, an insulating paper used in an oil-immersed electrical apparatus is predominantly composed of cellulose. Therefore, a typically-known deterioration marker substance is a degradation product of cellulose, such as furfural (in Patent Document 1 (Japanese Patent Laying-Open No. 04-337456), for example).

In recent years, JEC 2200 has been revised and the limit of temperature rise for transformers has been raised. This change to the limit of temperature rise has led to a widespread use of transformers the insulating paper of which is highly resistant to heat compared to an insulating paper predominantly composed of cellulose (herein, the insulating paper mentioned first is called a heat-resistant-treated insulating paper). The heat-resistant-treated insulating paper is used not only in mineral-oil-based transformers but also in vegetable-oil-based transformers.

Examples of the heat-resistant-treated insulating paper include an insulating paper that is made of cellulose to which an amine compound is added. As the insulating paper deteriorates, a degradation product of the cellulose and a deterioration product of the amine compound are produced. A typical degradation product of cellulose is furfural. Furfural chemically reacts with a deterioration product of an amine compound and, therefore, does not elute into the oil (see page 7, lines 7-9, of Non-patent Document 1 (ML. Coulibaly, C. Perrier, M. Marugan, “Assessment of Methanol as cellulose aging marker in mineral and ester oils”, CIGRE Conference, Paris, A2-112, 2016.), for example).

### SUMMARY OF THE INVENTION

An oil-immersed electrical apparatus including a heat-resistant insulating paper (an insulating paper containing an amine compound) has the following disadvantage:

the state of deterioration of the oil-immersed electrical apparatus cannot be accurately diagnosed, and therefore the remaining life of the oil-immersed electrical apparatus cannot be predicted, by a diagnostic technique that uses furfural as a deterioration marker substance.

The present invention aims at overcoming the disadvantage described above. An object of the present invention is to provide a method of diagnosing an oil-immersed electrical apparatus, a method capable of accurately assessing a state of deterioration of an oil-immersed electrical apparatus that includes an insulating paper containing an amine compound.

The present invention is related to a method of diagnosing an oil-immersed electrical apparatus by an assessment of a state of deterioration of the oil-immersed electrical apparatus, in which the oil-immersed electrical apparatus includes an insulating oil and an insulating paper and the insulating paper contains an amine compound.

This method includes the following:
performing a quantitative analysis of a marker substance contained in the insulating oil; and
assessing a state of deterioration of the oil-immersed electrical apparatus based on a quantified value of the marker substance obtained by the quantitative analysis.

The marker substance is a degradation product of cellulose. This degradation product of cellulose does not chemically react with a deterioration product of the amine compound.

According to the present invention, a method of diagnosing an oil-immersed electrical apparatus is provided, a method capable of accurately assessing a state of deterioration of an oil-immersed electrical apparatus that includes an insulating paper containing an amine compound.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a flowchart illustrating a method of diagnosing an oil-immersed electrical apparatus according to an embodiment 1.

FIG. 2 is a flowchart illustrating a specific example of the method of diagnosing an oil-immersed electrical apparatus according to embodiment 1.

FIG. 3 is an example of a chromatogram of a component contained in an insulating oil.

FIG. 4 is an example of a graph showing the correlation between a concentration, in oil, of a marker substance used in the method of diagnosing an oil-immersed electrical apparatus according to embodiment 1 and an average degree of polymerization of an insulating paper.

### DESCRIPTION OF THE PREFERRED EMBODIMENTS

In the following, embodiments according to the present invention will be described referring to drawings. In the drawings of the present invention, the same or equivalent members are denoted by the same reference numerals. Dimensions in the drawings, including length, width, thickness, and depth, may have been changed from the actual dimensions, as appropriate, for the clarification and simplification of the drawings. Therefore, dimensions may not agree with the actual dimensions.

### Embodiment 1.

A method of diagnosing an oil-immersed electrical apparatus according to the present embodiment assesses the state of deterioration of an oil-immersed electrical apparatus.

The oil-immersed electrical apparatus that is a subject of the diagnosis according to the present embodiment includes an insulating oil and an insulating paper (a heat-resistant-treated insulating paper), and the insulating paper contains an amine compound.

It is preferable that, within the oil-immersed electrical apparatus, an insulator, such as the insulating paper, and a conductor be immersed in the insulating oil. The insulating oil is not particularly limited, and may be either a mineral oil or a vegetable oil. Preferably, the oil-immersed electrical apparatus is a transformer.

The “state of deterioration of an(the) oil-immersed electrical apparatus” refers to, for example, the degree of deterioration of the oil-immersed electrical apparatus. By assessing the state of deterioration of the oil-immersed electrical apparatus and, then, using the correlation between the state of deterioration of the oil-immersed electrical apparatus and the remaining life of the oil-immersed electrical apparatus, estimation of the remaining life of the oil-immersed electrical apparatus may be carried out. The estimation of the remaining life makes it possible to propose a timely update of the oil-immersed electrical apparatus.

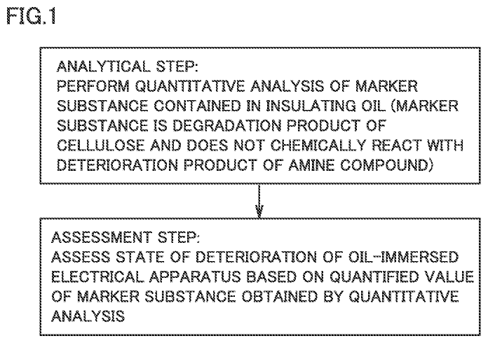

FIG. 1 is a flowchart illustrating the method of diagnosing an oil-immersed electrical apparatus according to the present embodiment. The method according to the present embodiment includes at least an analytical step and an assessment step.

### Analytical Step

In this step, a quantitative analysis of a marker substance contained in the insulating oil is carried out.

### Marker Substance

The marker substance is a degradation product of cellulose. This degradation product of cellulose does not chemically react with a deterioration product of an amine compound. This configuration allows for an accurate assessment of the state of deterioration of the insulating paper containing an amine compound (a heat-resistant-treated insulating paper) as well as the state of deterioration of the oil-immersed electrical apparatus including the insulating paper.

The “amine compound” refers to a compound that contains an amine, which arises when a hydrogen atom in ammonia is replaced by a substituent (for example, a hydrocarbon group or an aromatic atomic group). The amine compound is at least one of an amine and a derivative of an amine. The amine may be any one of a primary amine containing one substituent, a secondary amine containing two substituents, and a tertiary amine containing three substituents. Examples of the primary amine include dicyandiamide. The amine compound also includes a quaternary ammonium cation, which arises when an alkyl group is bound to a tertiary amine. The amine compound further includes ammonia.

Preferably, the “deterioration product of an amine compound” is a substance that chemically reacts with furfural. Examples of the deterioration product of an amine compound include basic substances. Examples of the basic substances include basic amine compounds (such as ammonia).

Because of these circumstances, it is preferable that the degradation product of cellulose used as the marker substance do not chemically react with a basic substance. Examples of the degradation product of cellulose that does not chemically react with a basic substance include an alcohol.

The alcohol is not particularly limited. Preferably, the alcohol has a boiling point that is higher than the operating temperature of the oil-immersed electrical apparatus (such as a transformer). The configuration in which the deterioration marker substance is an alcohol having a boiling point higher than the operating temperature allows for accurate diagnosis. When methanol or ethanol with a boiling point lower than the operating temperature of the transformer is used as the deterioration marker substance, the deterioration marker substance becomes dispersed into, for example, the space above the oil surface during operation and, therefore, correction is required for the measurement of the amount of the deterioration marker substance produced. In this case, an accurate diagnosis cannot be achieved.

Examples of the alcohol having a boiling point higher than the operating temperature of the oil-immersed electrical apparatus include furfuryl alcohol.

### Quantitative Analysis

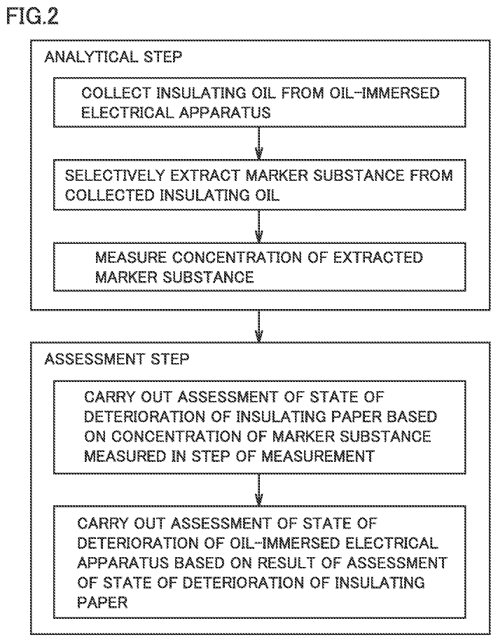

The technique used in the analytical step for the quantitative analysis of the marker substance contained in the insulating oil is not particularly limited provided that it allows for quantitative assessment of values related to the marker substance contained in the oil, such as the concentration of the marker substance. In the following, a description will be given of a specific example of the analytical step (quantitative analysis) according to the present embodiment referring to FIG. 2.

Referring to FIG. 2, the analytical step includes collecting the insulating oil from the oil-immersed electrical apparatus, subsequently selectively extracting the marker substance from the insulating oil thus collected, and then measuring the concentration of the marker substance thus extracted. In this way, the quantitative analysis of the marker substance contained in the insulating oil, such as the concentration of the marker substance, is achieved.

A more specific example is given below. The insulating oil collected from the oil-immersed electrical apparatus is passed through silica gel, and, thereby, the marker substance contained in the insulating oil is adsorbed on the silica gel. Then, acetonitrile is passed through the silica gel, and, thereby, the marker substance contained in the insulating oil is collected in the acetonitrile. Subsequently, high-performance liquid chromatography is carried out to perform quantitative analysis (measurement) of the marker substance.

A solid-phase extraction technique, like the one described above, allows for an analysis of the marker substance contained in the insulating oil with high sensitivity devoid of any influence of an interfering substance contained in the insulating oil.

Preferably, the marker substance thus selectively extracted from the insulating oil is subjected to derivatization before subjected to high-performance liquid chromatography. The derivatization is capable of increasing the sensitivity of the quantitative analysis of the marker substance.

Examples of the derivatization include HPLC labeling. Specific examples of the technique of the HPLC labeling include a technique involving adding DBD-COCl (4-(N,N-dimethylaminosulfonyl)-7-(N-chloroformylmethyl-N-methylamino)-2,1,3-ben zoxadiazole, which is a derivatization reagent) and quinuclidine (a catalyst) to a sample containing the marker substance, followed by immersing the resulting sample in a water bath at 60° C. for 30 minutes.

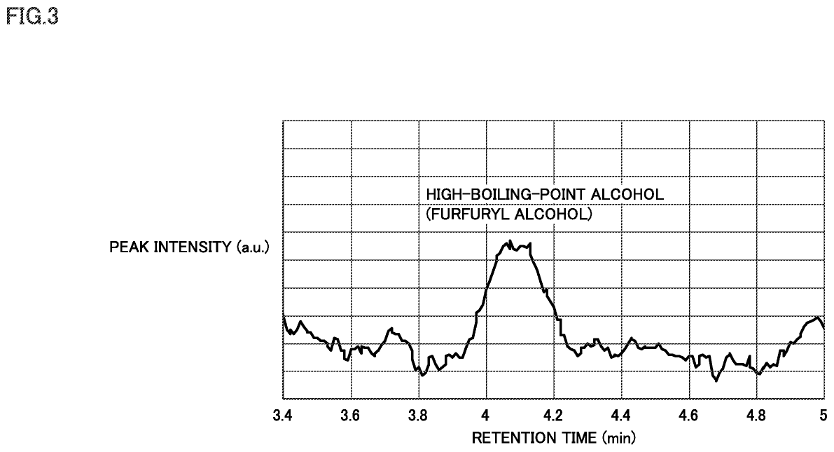

The derivatization of the marker substance allows for detection of a peak of a desired marker substance, as seen in FIG. 3, and thereby is capable of increasing the sensitivity of the quantitative analysis of the marker substance. FIG. 3 is an example of a chromatogram of furfuryl alcohol, which is obtained by chromatography performed after derivatization (labeling) of furfuryl alcohol with DBD-COCl and quinuclidine.

### Assessment Step

In this step, the state of deterioration of the oil-immersed electrical apparatus is assessed based on a quantified value (such as a concentration) of the marker substance obtained by the quantitative analysis.

A specific technique of the assessment in the assessment step is not particularly limited provided that it is capable of assessing the state of deterioration of the oil-immersed electrical apparatus based on a quantified value of the marker substance. In the following, a description will be given of a specific example of the assessment step according to the present embodiment referring to FIG. 2.

Preferably, as shown in FIG. 2, the assessment step includes carrying out an assessment of the state of deterioration of the insulating paper based on the concentration of the marker substance measured in the step of measurement and then, based on a result of the assessment of the state of deterioration of the insulating paper, carrying out an assessment of the state of deterioration of the oil-immersed electrical apparatus.

Preferably, the assessment of the state of deterioration of the insulating paper based on a quantified value of the marker substance is carried out in the following manner:

an estimation of an average degree of polymerization of the insulating paper is carried out based on the quantified value of the marker substance in which the estimation is carried out by using an expression of the correlation between the quantified value of the marker substance and an average degree of polymerization of the insulating paper (the expression is obtained in advance by measurement of a reference material and the like); and

the assessment of the state of deterioration of the insulating paper is carried out based on a result of the estimation of an average degree of polymerization.

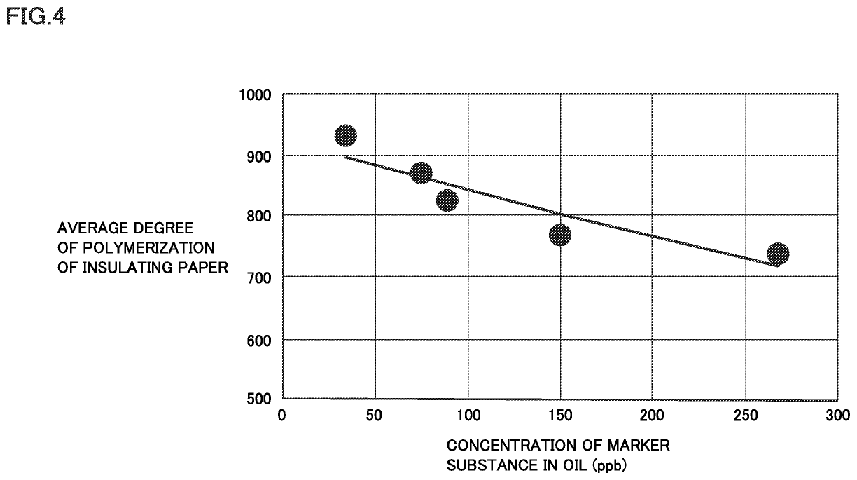

FIG. 4 is an example of a graph showing the correlation between the concentration, in the oil, of the marker substance used in the method of diagnosing an oil-immersed electrical apparatus and an average degree of polymerization of the insulating paper. By using this graph and obtaining a regression line by a least square method or the like, the above-mentioned expression may be obtained.

For instance, the assessment of the state of deterioration of the insulating paper is carried out in the following manner: the greater the decrement of the degree of polymerization observed in the result of the estimation of the average degree of polymerization of the insulating paper relative to the initial average degree of polymerization of the insulating paper is, the greater the degree of deterioration of the insulating paper is rated to be.

It is preferable that, as the expression of the correlation between the quantified value of the marker substance and an average degree of polymerization of the insulating paper, a different expression be used depending on the type of the insulating oil. A mineral oil and a vegetable oil are different in oil type and are different in the solubility of the deterioration marker substance in it. For this reason, by using a different expression depending on the type of the insulating oil (for example, a mineral oil or a vegetable oil) as the expression of the correlation between the quantified value of the marker substance and an average degree of polymerization of the insulating paper, an accurate estimation of the average degree of polymerization may be achieved.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A method of diagnosing an oil-immersed electrical apparatus by an assessment of a state of deterioration of the oil-immersed electrical apparatus, the oil-immersed electrical apparatus including an insulating oil and an insulating paper, the insulating paper containing an amine compound, the method comprising:
performing a quantitative analysis of a marker substance contained in the insulating oil; and
assessing a state of deterioration of the oil-immersed electrical apparatus based on a quantified value of the marker substance obtained by the quantitative analysis,
the marker substance being a degradation product of cellulose, the degradation product of cellulose not chemically reacting with a deterioration product of the amine compound.

2. The method according to claim 1, wherein the deterioration product of the amine compound is a basic substance.

3. The method according to claim 1, wherein the marker substance is an alcohol.

4. The method according to claim 3, wherein the alcohol has a boiling point that is higher than an operating temperature of the oil-immersed electrical apparatus.

5. The method according to claim 1, wherein in the assessing,
an assessment of a state of deterioration of the insulating paper is carried out based on the quantified value of the marker substance, and
the assessment of a state of deterioration of the oil-immersed electrical apparatus is carried out based on a result of the assessment of a state of deterioration of the insulating paper.

6. The method according to claim 5, wherein in the assessment of a state of deterioration of the insulating paper based on the quantified value of the marker substance,
an estimation of an average degree of polymerization of the insulating paper is carried out based on the quantified value of the marker substance, the estimation being carried out by using an expression of a correlation between the quantified value of the marker substance and an average degree of polymerization of the insulating paper, and
the assessment of a state of deterioration of the insulating paper is carried out based on a result of the estimation of an average degree of polymerization.

7. The method according to claim 6, wherein, as the expression of a correlation between the quantified value of the marker substance and an average degree of polymerization of the insulating paper, a different expression is used depending on a type of the insulating oil.
